(19) United States
(12) Patent Application Publication
(10) Pub. No.: US 2006/0286358 A1
(43) Pub. Date: Dec. 21, 2006

(54) Heat spreader for use with light emitting diode

(76) Inventor: Steven A. Tower, Silva, MO (US)

Correspondence Address: WIGGIN AND DANA LLP;ATTENTION: PATENT DOCKETING, ONE CENTURY TOWER, P.O. BOX 1832, NEW HAVEN, CT, 06508-1832, US

(21) Appl. No.: 11/374,832

(22) Filed: Mar. 14, 2006

Related U.S. Application Data
(60) Provisional application No. 60/661,524, filed on Mar. 14, 2005.

(51) Int. Cl. B32B 3/00; H05K 1/00

(52) U.S. Cl. 428/209; 174/258

(57) ABSTRACT

A substrate for an integrated circuit device includes a low coefficient of thermal expansion material having opposing first and second surfaces with an array of through holes extending from the first surface to the second surface. A high thermal conductivity substrate is adjacent to the second surface of the low coefficient of thermal expansion material and a wettable material bonds the low coefficient of thermal expansion material to the high thermal conductivity substrate while also substantially filling said array of through holes. An integrated circuit device, such as a light emitting diode, may be bonded to the first surface of the low coefficient of thermal expansion material by a compliant die attach material.

### CROSS REFERENCE TO RELATED APPLICATION(S)

This application claims the benefit of U.S. Provisional Application No. 60/661,524, filed Mar. 14, 2005.

### BACKGROUND OF THE INVENTION

1. Field of the Invention

This invention relates to composite heat spreaders, and more particularly to heat spreaders having an iron-nickel-base alloy component and a copper-base alloy component. The composite heat spreader has a coefficient of thermal expansion (CTE) and a thermal conductivity effective for mounting a light emitting diode (LED).

2. Description of the Related Art

Solid state lighting, such as light emitting diodes, has many advantages over traditional light sources such as incandescent and florescent. Such advantages include longer life and higher efficiency. Unlike traditional light sources that dissipate energy lost as heat in the radiant beam of light, the heat energy developed during operation of an LED does not radiate away from the LED in the light beam area, but conducts back through the semiconductor material making up the LED. As a result, the LED must be mounted to an efficient heat sink.

The semiconductor material making up the LED has a relatively low coefficient of thermal expansion (CTE). Therefore, traditional heat sink material such as copper and aluminum having relatively high coefficients of thermal expansion are not be used. Rather, composite materials, such as a three layer clad of copper/molybdenum/copper, are utilized. However, the intervening molybdenum layer, while effective to reduce the coefficient of thermal expansion the composite, reduces the effectiveness of the transfer of heat.

It is known to form a composite material having a lattice formed from a low CTE material, such as an iron nickel alloy. The lattice has an array of holes that are filled with a good thermal conductor such as copper or a copper-base alloy. Such a composite material is disclosed in U.S. Pat. No. 4,427,993 to Fichot, et al. However, it is possible for the copper inserts to be dislodged from the lattice. Air is an effective thermal insulator and gaps between the lattice and the copper inserts could cause hot spots which potentially could damage the LED device. Through out this patent application, “-base” when appended to an element, such as copper-base, is given its common metallurgical definition, namely the alloy contains at least 50%, by weight, of the -base element.

It is also known to sandwich a layer of copper between two layers of an iron-nickel alloy lattice and cause the copper to flow up through an array of holes formed in the lattice by application of pressure, such as by passing the assembly through a rolling mill. This composite is disclosed in U.S. Pat. No. 4,283,464 to Hascoe. However, it is difficult to achieve complete filling of the entire array of holes and there remains a possibility of air gaps. Further, distortion of the array of holes is possible when compressed between rolling mill rollers. Both the Fichot et al. and Hascoe patent are incorporated by reference in their entireties herein.

There remains, therefore, a need for a heat spreader for LEDs that does not suffer from the disadvantages of the prior art.

### BRIEF SUMMARY OF THE INVENTION

In accordance with a first embodiment of the invention, there is provided a substrate for an integrated circuit device. The substrate includes a low coefficient of thermal expansion material having opposing first and second surfaces with an array of through holes extending from the first surface to the second surface. A high thermal conductivity substrate is adjacent to the second surface of the low coefficient of thermal expansion material and a wettable material bonds the low coefficient of thermal expansion material to the high thermal conductivity substrate while also substantially filling said array of through holes.

It is a feature of this first embodiment that an integrated circuit device, such as a light emitting diode, may be bonded to the first surface of the low coefficient of thermal expansion material by a compliant die attach material.

In accordance with a second embodiment of the invention, there is provided a method for the manufacture of a composite heat spreader which includes providing a low coefficient of thermal expansion material having opposing first and second surfaces with an array of through holes extending from said first surface to said second surface, disposing a high thermal conductivity substrate adjacent to the second surface and a wettable material adjacent to the first surface and then heating to a temperature effective to cause the wettable material to melt thereby bonding the second surface to the high thermal conductivity substrate and further to substantially fill the array of through holes.

It is a feature of this second embodiment that an integrated circuit device, such as a light emitting diode, may be bonded to the first surface of the low coefficient of thermal expansion material.

It is another feature of the invention, that the high thermal conductivity material may be selected to be a work hardenable copper alloy. In this instance, the composite heat spreader may be worked after the heating step of the second embodiment to increase tensile strength.

The details of one or more embodiments of the invention are set forth in the accompanying drawings and the description below. Other features, objects and advantages of the invention will be apparent from the description and drawings, and from the claims.

### BRIEF DESCRIPTION OF THE DRAWINGS

FIG. 1 illustrates in partial perspective a method to manufacture the heat spreader of the present invention.

FIG. 2 illustrates in cross sectional representation an LED device mounted to the heat spreader of the present invention.

Like reference numbers and designations in the various drawings indicated like elements.

### DETAILED DESCRIPTION

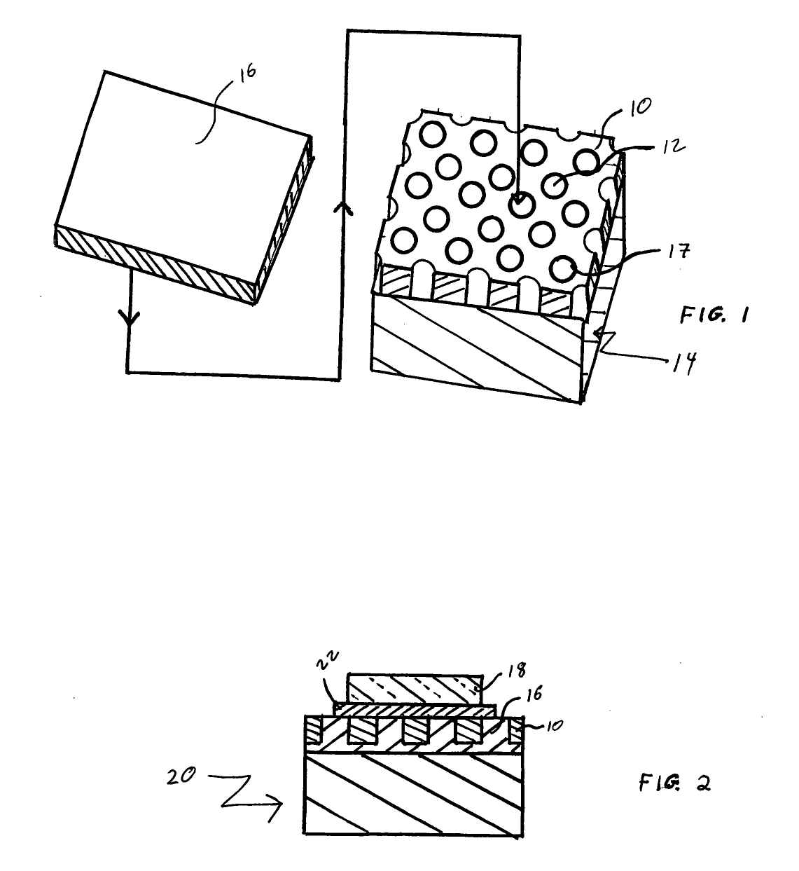

With reference to FIG. 1, a relatively low coefficient of thermal expansion material 10, such as an iron/nickel-base alloy, is provided with an array of through holes 12. By relatively low CTE material, it is meant that the material has a coefficient of thermal expansion of less than 7 parts per million per degree centigrade (7 ppm/° C.) over the temperature range of room temperature (nominally 22° C.) to 350° C. Suitable materials, having nominal compositions specified in weight percent, include the material sold under the trademark KOVAR, which is 29% nickel-17% cobalt-balance iron; the material sold under the trademark INVAR, which is 36% nickel-balance iron; and the material sold under the trademark ALLOY 42, which is 42% nickel-balance iron.

The through holes 12 are formed by any suitable process such as photolithography and occupy a minimum of 50% of the surface area of the low CTE material. More preferably, from 75 to 90% of the surface area of the low CTE material is occupied by the holes. Most preferably, approximately 80% of the surface area of the low coefficient of thermal expansion material 10 is occupied by the through holes 12. The low CTE material 10 has a thickness sufficient to restrain thermal expansion and preferably ranges from 0.0015 inch to 0.015 inch and more preferably ranges from 0.002 inch to 0.01 inch and most preferably ranges from 0.003 inch to 0.005 inch.

The low CTE material 10 is placed on a high thermal conductivity substrate 14 such as copper, silver, aluminum or an alloy thereof. Silver is less preferred due to cost and aluminum is less preferred due to poor wettability to solders and brazes as discussed herein below. Also, the melting temperature of aluminum is too low for effective use with the preferred brazing materials. However, aluminum or an aluminum base alloy coated with a solder- or braze-wettable material could prove effective. Preferably, the high thermal conductivity substrate 14 is copper or a copper base alloy. Most preferred are work hardenable copper base alloys such as those designated by the Copper Development Association (CDA—New York, N.Y.) as C11000 (electrolytic tough pitch copper having a nominal composition, by weight, of 99.95% Cu and 0.04% oxygen); C15000 (zirconium-copper having a nominal composition, by weight, of 99.85% Cu and 0.15% Zr); and C19700 (nominal composition, by weight, 99.15% Cu, 0.6% Fe, 0.2% P and 0.05% Mg).

The high thermal conductivity substrate 14 has a thickness of between 0.005 inch and 0.1 inch. More preferably, the thickness is between 0.01 inch and 0.025 inch and most preferably from about 0.012 inch to about 0.018 inch.

A wettable material 16 is placed on a first surface 17 of the low CTE material 10 on a side opposite from the high thermal conductivity substrate 14. The wettable material 16 is any material that when molten will wet and adhere to both the low CTE material 10 and the high thermal conductivity substrate 14. When the low CTE material is an iron nickel alloy and the high thermal conductivity substrate is copper or a copper base alloy, or a coating of copper or a copper base alloy, solders predominantly formed of copper and silver are suitable as the wettable material. A most preferred solder is the copper/silver eutectic commonly referred to as CuSil. CuSil has a nominal composition of 28.1% by weight copper and the balance silver and a melting point of 779.1° C.

With the wettable material 16 positioned on first surface 17 of the low coefficient of thermal expansion material 10, the assembly is heated in a reducing atmosphere, such as a mixture of nitrogen and hydrogen, to a temperature effective to flow the wettable material and to bond it to both the low CTE material 10 and the high thermal conductivity substrate 12. For CuSil, a suitable process temperature is 800°.

The high temperatures required to flow the wettable material 16 results in annealing of the high thermal conductivity substrate 14. It is desirable to increase the strength of the high thermal conductivity substrate subsequent to this anneal. An increase in strength may be achieved by work hardening when a work hardenable copper alloy is selected. Work hardening may be effected by high pressure, on the order of 65 tons per square inch, stamping or rolling.

With reference to FIG. 2, a light emitting diode 18 is bonded to the first surface 17 of the low CTE material 10 which comprises a composite of low CTE material 10 and wettable material 16. Since there is likely a coefficient of thermal expansion mismatch between the LED 18 and composite heat spreader 20, a thermally conductive compliant die attach material 22, such as a tin/lead or tin/lead/silver solder is used. Non-lead based solders, such as indium based solders work equally well.

While FIG. 2 shows the first surface 17 have a low CTE material 10 matrix interspersed with wettable material 16, it is likely that a thin coating, on the order of 0.001 inch to 0.005 inch of wettable material will coat the first surface following the flow step.

One or more embodiments of the present invention have been described. Nevertheless, it will be understood that various modifications may be made without departing from the spirit and scope of the invention. Accordingly, other embodiments are within the scope of the following claims.

What is claimed is:

1. A substrate for an integrated circuit device, comprising:
a low coefficient of thermal expansion material having opposing first and second surfaces and an array of through holes extending from said first surface to said second surface;
a high thermal conductivity substrate adjacent said second surface of said low coefficient of thermal expansion material; and
a wettable material bonding said low coefficient of thermal expansion material to said high thermal conductivity substrate and also substantially filling said array of through holes.

2. The substrate of claim 1 wherein said low coefficient of thermal expansion material is an alloy containing iron and nickel.

3. The substrate of claim 2 wherein said low coefficient of thermal expansion material is selected from the group consisting of the materials sold under the trademarks KOVAR, INVAR, and ALLOY 42.

4. The substrate of claim 2 wherein said high thermal conductivity substrate is copper or a copper-base alloy.

5. The substrate of claim 4 wherein said high thermal conductivity substrate is a work hardenable copper alloy.

6. The substrate of claim 5 wherein said wettable material is an alloy containing silver and copper.

7. The substrate of claim 6 wherein said wettable material is the silver/copper eutectic.

8. The substrate of claim 5 wherein said array of through holes occupies at least 50% of the surface area of said first surface and said through holes are substantially filled with said wettable material.

9. The substrate of claim 8 wherein said array of through holes occupies from 75% to 90%, by area, of said first surface.

10. An assembly including an integrated circuit device and a heat spreader, comprising:
said heat spreader including a low coefficient of thermal expansion material having opposing first and second surfaces and an array of through holes extending from said first surface to said second surface, a high thermal conductivity substrate adjacent said second surface of said low coefficient of thermal expansion material, and a wettable material bonding said low coefficient of thermal expansion material to said high thermal conductivity substrate and also substantially filling said array of through holes; and
said integrated circuit device bonded to said first surface of said low coefficient of thermal expansion material by a compliant die attach material.

11. The assembly of claim 10 wherein said low coefficient of thermal expansion material is an alloy containing iron and nickel.

12. The assembly of claim 11 wherein said low coefficient of thermal expansion material is selected from the group consisting of the materials sold under the trademarks KOVAR, INVAR, and ALLOY 42.

13. The assembly of claim 11 wherein said high thermal conductivity substrate is copper or a copper-base alloy.

14. The assembly of claim 13 wherein said high thermal conductivity substrate is a work hardenable copper alloy.

15. The assembly of claim 14 wherein said wettable material is an alloy containing silver and copper.

16. The assembly of claim 15 wherein said wettable material is the silver/copper eutectic.

17. The assembly of claim 14 wherein said array of through holes occupies at least 50% of the surface area of said first surface and said through holes are substantially filled with said wettable material.

18. The assembly of claim 17 wherein said array of through holes occupies from 75% to 90%, by area, of said first surface.

19. The assembly of claim 18 wherein said integrated circuit device is bonded to said heat spreader by a compliant solder.

20. The assembly of claim 19 wherein said compliant solder is selected from the group consisting of tin/lead alloys, tin/lead/silver alloys and indium-base alloys.

21. The assembly of claim 19 wherein said integrated circuit device is a light emitting diode.

22. A method for the manufacture of a composite heat spreader, comprising the steps of:
providing a low coefficient of thermal expansion material having opposing first and second surfaces with an array of through holes extending from said first surface to said second surface;
disposing a high thermal conductivity substrate adjacent said second surface and a wettable material adjacent said first surface; and
heating to a temperature effective to cause said wettable material to melt thereby bonding said second surface to said high thermal conductivity substrate and further to substantially fill said array of through holes.

23. The method of claim 22 including selecting said low coefficient of thermal expansion material to be an iron/nickel alloy, said high thermal conductivity alloy to be a work hardenable copper alloy and said wettable material to be effective to wet both said iron/nickel alloy and said work hardenable copper alloy.

24. The method of claim 23 including selecting said wettable material to be a solder containing both copper and silver.

25. The method of claim 24 wherein said heating step is to a temperature of from 22° C. to 800° C. in an atmosphere of a nitrogen/hydrogen mixture.

26. The method of claim 25 wherein subsequent to said heating step, said composite heat spreader is worked to increase the tensile strength of said work hardenable copper alloy.

27. The method of claim 26 wherein said working step includes pressing or rolling to a pressure in excess of 65 tons per square inch.

28. The method of claim 27 wherein subsequent to said working step, an integrated circuit device is bonded to said first surface of said low coefficient of thermal expansion material.

29. The method of claim 28 including selecting said integrated circuit device to be a light emitting diode.
